(19) United States
(12) Patent Application Publication
(10) Pub. No.: US 2013/0017666 A1
(43) Pub. Date: Jan. 17, 2013

(54) METHOD OF FORMING ISOLATION STRUCTURE

(71) Applicant: Jui Hsuan Chung, New Taipei City (TW)

(72) Inventor: Jui Hsuan Chung, New Taipei City (TW)

(73) Assignee: NANYA TECHNOLOGY CORPORATION, Kueishan (TW)

(21) Appl. No.: 13/181,639

(22) Filed: Jul. 13, 2011

(51) Int. Cl. H01L 21/31

(52) U.S. Cl. 438/429; 438/400; 257/E21.24

(57) ABSTRACT

A method of forming an isolation structure includes the steps of forming an insulating spacer on the side surfaces of a trench in a substrate, exposing a portion of the substrate, growing an epitaxial silicon layer above a bottom surface of the trench, oxidizing the epitaxial silicon layer to form a thermal oxide layer, and filling a portion of the trench above the thermal oxide layer with a dielectric material.

### TECHNICAL FIELD

The present invention relates to a method of forming a semiconductor structure. More particularly, the present invention relates to a method of forming an isolation structure.

### BACKGROUND

Recently, as the rapid development of integrated circuit fabrication processes, the number of elements in a chip has increased, and element size and integration density has increased. For example, element pitch requirements for integrated circuit fabrication processes have evolved from micron level to nanometer level. Regardless of the reduction in element size, however, it requires adequate insulations or isolations among elements in a chip so as to achieve the optimal performance. This technique is so-called device isolation technology. Well-fabricated insulations or isolations among elements can reduce element size as much as possible, ensure superior isolation, and create more space for more elements in a chip.

Among the different element isolation techniques, shallow trench isolation (STI) technique is commonly used to electrically isolate electronic devices from each other, so as to avoid short circuits and cross interference. STI is generally applied in semiconductor processes such as a CMOS process, filled with dielectric material by chemical vapor deposition (CVD), for example. With the width of the STI trenches getting smaller and trench aspect ratios increasing, trenches with narrow openings and high aspect ratios can degrade the forming of the dielectric material therein, and problems such as pinch-off near the top of the trench or the creation of voids are becoming important issues with the use of CVD.

In view of the above issues, the conventional trench filling methods have many problems. Therefore, there is a need for a method of forming an isolation structure and semiconductor device with the isolation structure.

### SUMMARY

One aspect of the present invention discloses a method of forming an isolation structure, and the method comprises the steps of forming a trench in a substrate, wherein the trench comprises side surfaces and a bottom surface; forming an insulating spacer on the side surfaces of the trench, and the insulating spacer exposing a portion of the substrate; growing an epitaxial silicon layer above the bottom surface of the trench; oxidizing the epitaxial silicon layer to form a thermal oxide layer; and filling a portion of the trench above the thermal oxide layer with a dielectric material.

Another aspect of the present invention discloses a method of forming an isolation structure, and the method comprises the steps of forming an upper layer on a substrate, wherein the upper layer comprises at least one trench having side surfaces and exposes a portion of the substrate; forming an insulating spacer on the side surfaces of the trench, and the insulating spacer exposing a portion of the substrate; growing an epitaxial silicon layer from the substrate; oxidizing the epitaxial silicon layer to form a thermal oxide layer; filling a portion of the trench above the thermal oxide layer with a dielectric material; and removing the upper layer.

The foregoing has outlined rather broadly the features of the present invention in order that the detailed description of the invention to follow may be better understood. Additional features of the invention will be described hereinafter and form the subject of the claims of the invention. It should be appreciated by those skilled in the art that the concept and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a cross-sectional view showing a substrate including trenches according to one embodiment of the present invention;

FIG. 2 is a cross-sectional view showing an insulating spacer formed on the side surfaces of each trench according to one embodiment of the present invention;

FIG. 3 is a cross-sectional view showing an insulating spacer formed on the side surfaces and the bottom surface of each trench according to one embodiment of the present invention;

FIGS. 4 and 5 are cross-sectional views showing an epitaxial silicon layer formed above the bottom surface of each trench according to one embodiment of the present invention;

FIGS. 6 and 7 are cross-sectional views showing a thermal oxide layer formed in the low portion of each trench according to one embodiment of the present invention;

FIGS. 8 and 9 are cross-sectional views showing a dielectric material filling the trenches according to one embodiment of the present invention;

FIGS. 10 and 11 are cross-sectional views showing isolation structures in respective substrates according to one embodiment of the present invention;

FIG. 12 is a cross-sectional view showing an upper layer formed on a substrate and including trenches according to one embodiment of the present invention;

FIG. 13 is a cross-sectional view showing an insulating spacer formed on the side surfaces of each trench according to one embodiment of the present invention;

FIG. 14 is a cross-sectional view showing an epitaxial silicon layer formed on the bottom surface of each trench according to one embodiment of the present invention;

FIG. 15 is a cross-sectional view showing a thermal oxide layer formed in the low portion of each trench according to one embodiment of the present invention;

FIG. 16 is a cross-sectional view showing a dielectric material filling the trenches according to one embodiment of the present invention;

FIG. 17 is a cross-sectional view showing undesired dielectric materials being removed according to one embodiment of the present invention; and

FIG. 18 is a cross-sectional view showing an isolation structure on the substrate according to one embodiment of the present invention.

### DETAILED DESCRIPTION

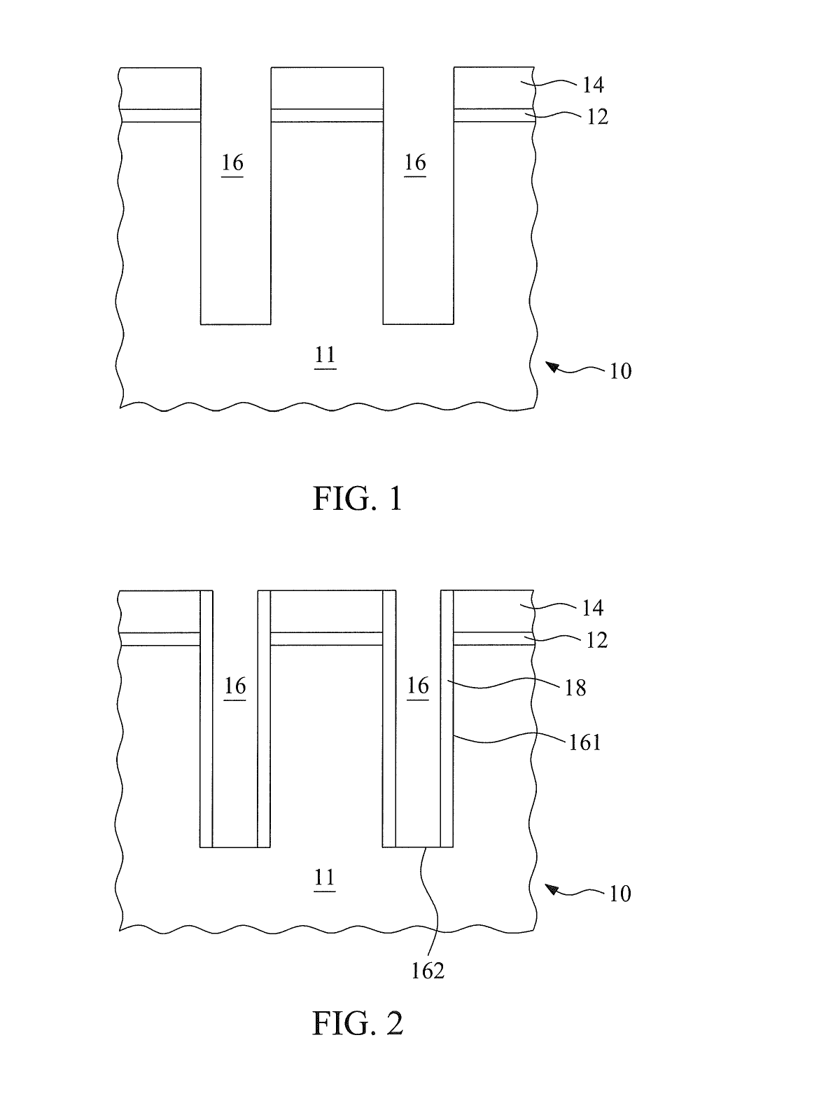

FIGS. 1 to 11 are cross-sectional views showing a method of forming isolation structures according to one embodiment of the present invention. As shown in FIG. 1, a substrate 10 which includes a silicon layer 11, a thin oxide 12 and a hard mask 14 is provided. The thin oxide 12 is formed on the silicon layer 11, and the hard mask layer 14 is formed on the thin oxide 12 with a thickness, for example, in a range of 200 to 1500 angstroms. The hard mask layer 14 can be a layer of silicon nitride, which can be formed by chemical vapor deposition. The hard mask 14 is able to be used as a stop for the chemical mechanical polishing (CMP) process.

A photoresist mask (not shown) can be provided to etch out trenches 16 in the substrate 10. The photoresist mask may be formed by using a conventional photolithographic process. After the trenches 16 are formed in the substrate 10, the photoresist mask may be selectively removed by a conventional resist strip process.

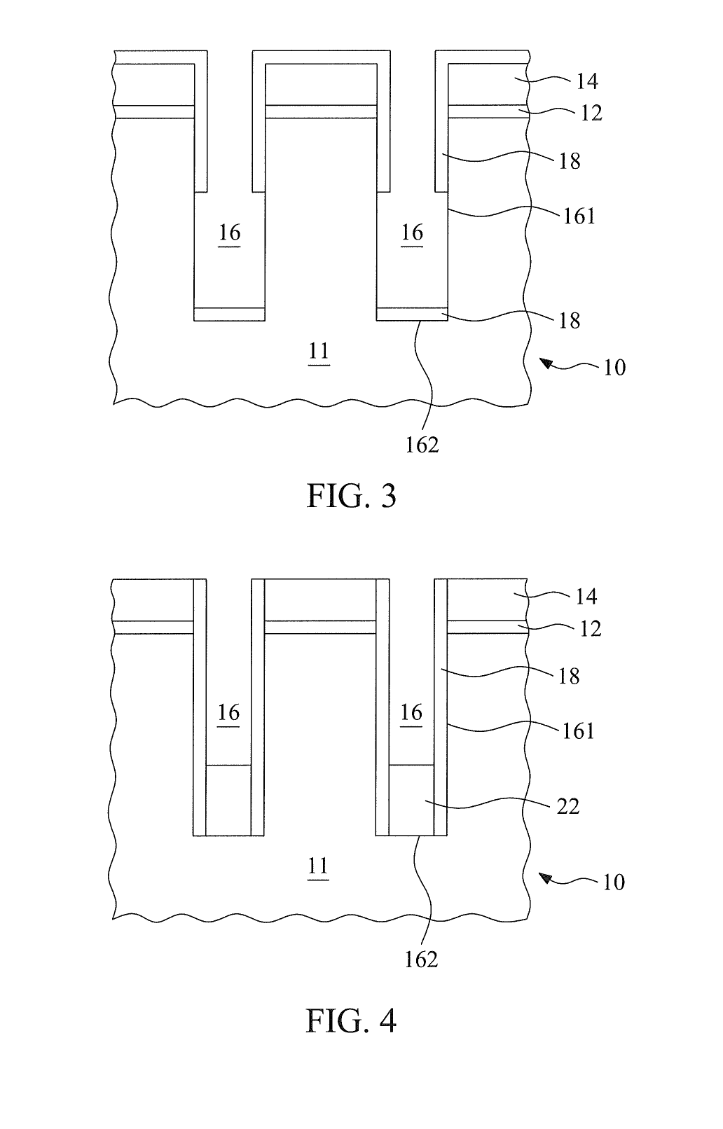

Referring to FIG. 2, in this embodiment, an insulating spacer 18 is formed on the side surfaces 161 of the trenches 16 by atomic layer deposition (ALD), for example, and parts of the substrate 10 are exposed. It should be noted that the insulating spacer 18 may be formed on the side surfaces 161 and the bottom surface 162 of the trench 16, exposing part of the side surfaces 161 (see FIG. 3). The insulating spacer 18 can repair the damage of the side surfaces 161 if the trenches 16 are etched by reactive ion etching.

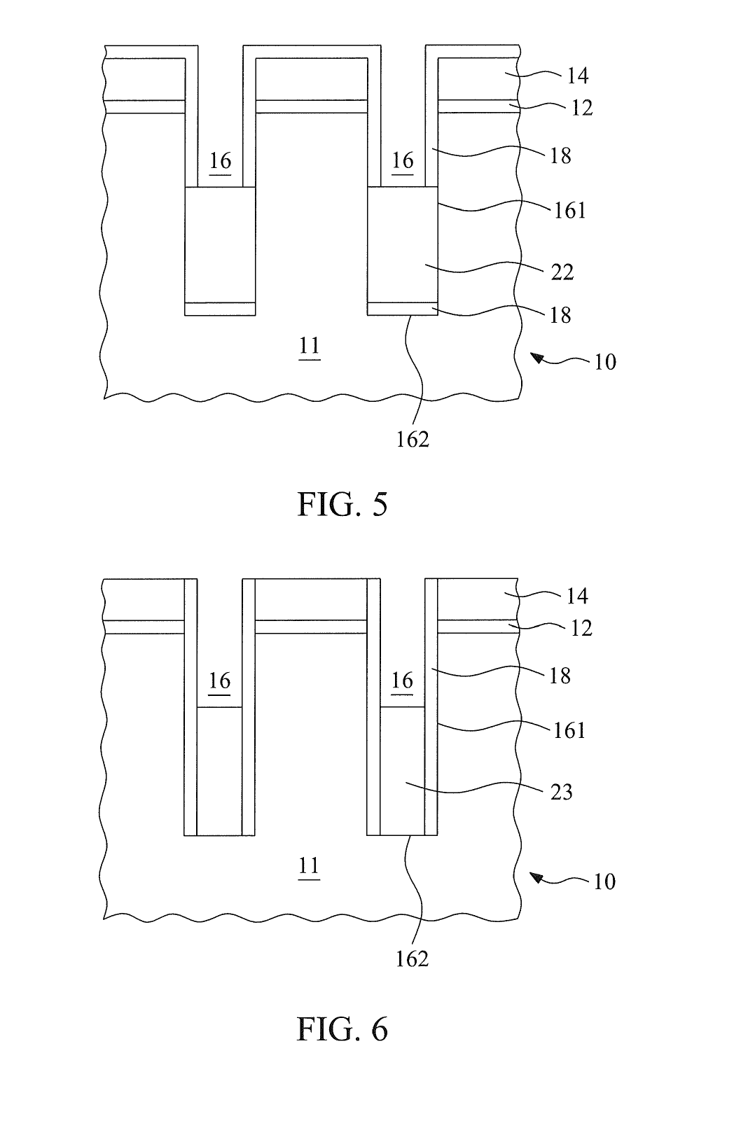

Referring to FIG. 4, an epitaxial silicon layer 22 is formed above the bottom surface 162 of the trench 16, and located between the insulating spacer 18. In this embodiment, epitaxial deposition of silicon is carried out to grow the epitaxial silicon layer 22 on the bottom surface 162 of each trench 16. Epitaxial silicon growth is applied to areas of the exposed part of the silicon layer 11. In each trench 16, the insulating spacer 18 is formed in a manner that covers the side surfaces 161 of the trench 16 while exposing the bottom surface 162 of the trench 16; thus, epitaxial silicon grows on the bottom surface 162. In one embodiment as illustrated by FIG. 5, epitaxial deposition of silicon is carried out to grow the epitaxial silicon layer 22 on the side surfaces 161 and the bottom surface 162 of each trench 16. Because the insulating spacer 18 can prevent epitaxial silicon growth, the epitaxial silicon can prevent the trench 16 from pinching off during the epitaxial deposition process. Furthermore, the epitaxial silicon layer 22 in the trench 16 can reduce the aspect ratio.

Specifically, the epitaxial silicon can be grown using vapor-phase epitaxy. The epitaxial silicon can be formed from a material including chlorine, and traces of chlorine may be left in the epitaxial silicon layer 22 after it is formed.

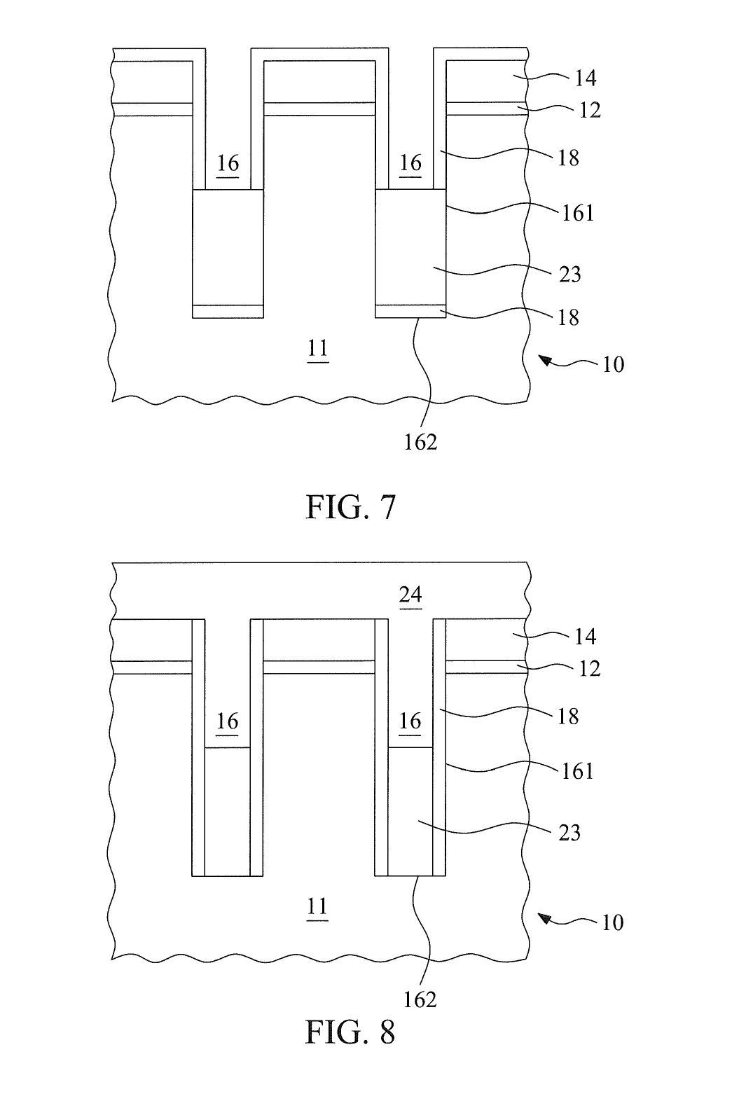

After the epitaxial silicon layer 22 is formed, the epitaxial silicon layer 22 is subjected to thermal oxidation to transform it into a thermal oxide (silicon oxide) layer 23 as shown in FIGS. 6 and 7. Preferably, steam oxidation at a temperature of approximately 800 to 1000 degrees Celsius is employed for such transformation. The thermal oxide layer 23 can have greater density than that of a conventional oxide layer formed by deposition. The thermal oxidation may oxidize at least a portion of the epitaxial silicon layer 22, or oxidize the epitaxial silicon layer 22 completely.

After the thermal oxidation process is finished, the lower portion of the trench 16 is filled with the thermal oxide layer 23. As such, the depth of the filling space as well as the aspect ratio of the trench 16 are reduced. The height of the thermal oxide layer 23 depends on the embodiments employed. In one embodiment, the thermal oxide layer 23 expands to an extent such that the aspect ratio of the remaining portion of the trench 16, above the thermal oxide layer 23, is reduced.

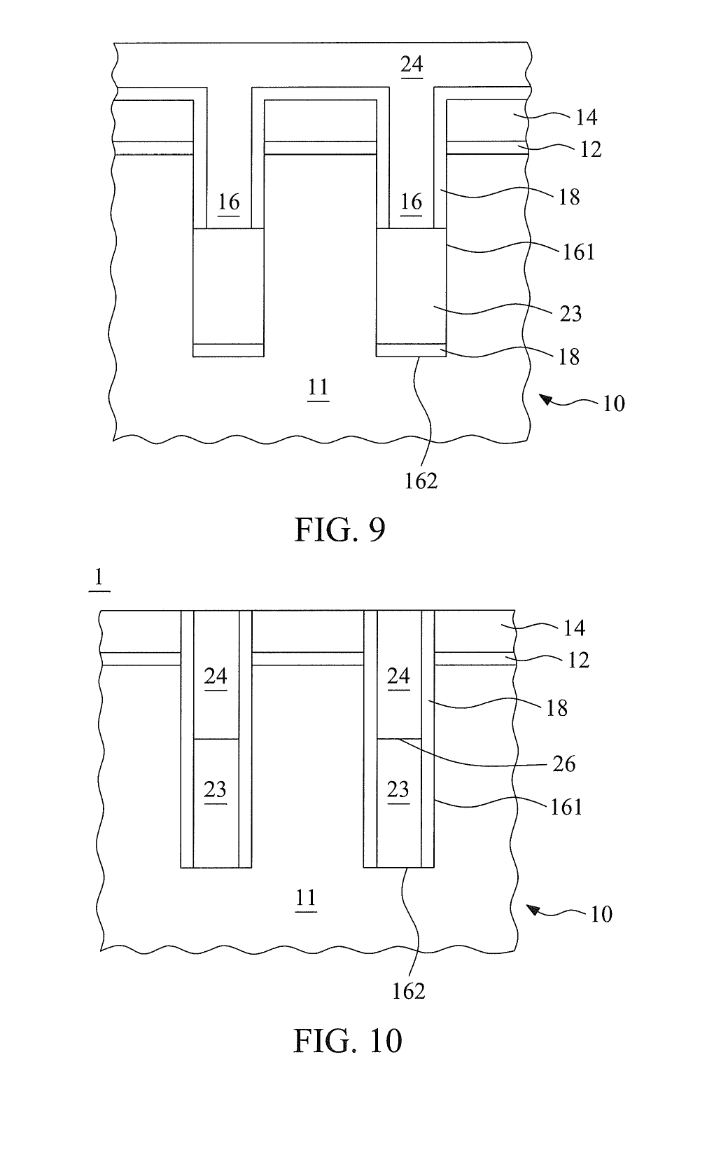

As shown in FIGS. 8 and 9, after the thermal oxide layer 23 is formed, a dielectric material 24, such as silicon oxide, is deposited to fill the remaining portion of the trench 16. Conventional processes may then follow to form a semiconductor device such as a memory, microcontroller, analog circuitry, etc. The dielectric material 24 can be deposited using a chemical vapor deposition process. The dielectric material 24 can alternatively be formed using a spin-on deposition process, and subsequently solidified and densified. In addition to the aforementioned deposition processes, other processes for filling trenches are applicable.

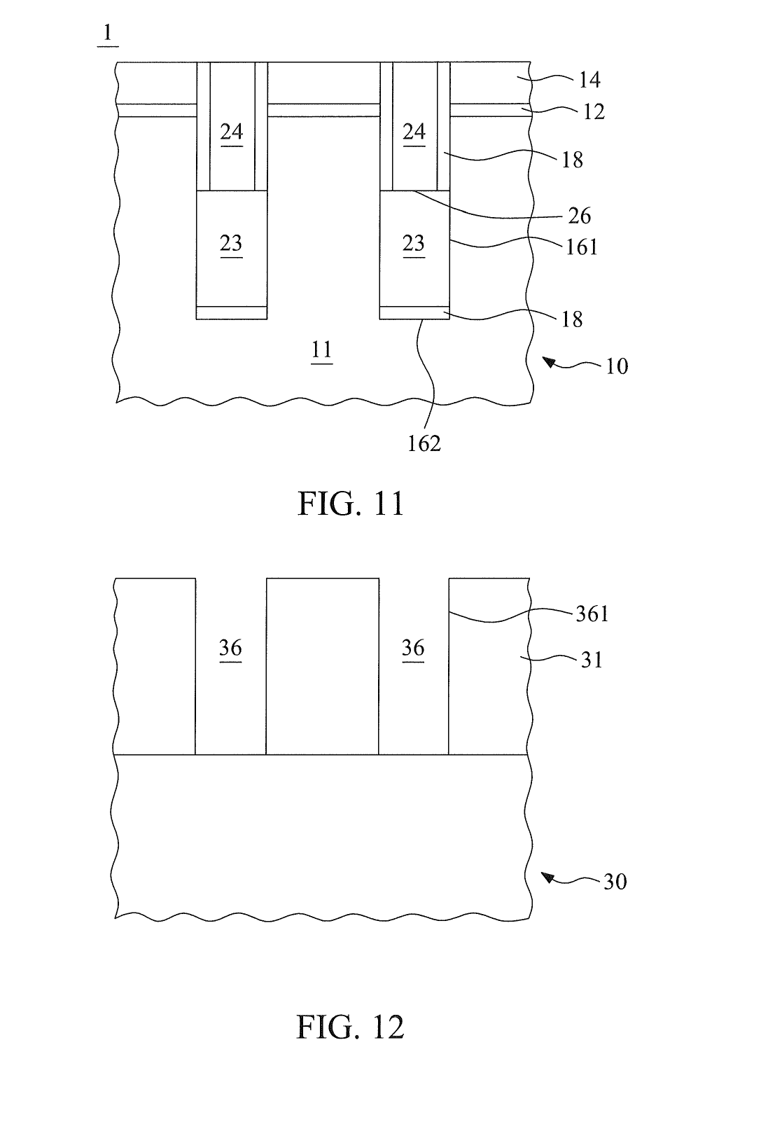

It should be noted that after the trenches 16 are fully filled, a chemical-mechanical polishing process or other suitable processes may be used to remove undesired dielectric materials 24. Consequently, an isolation structure 1 is completed (as shown in FIGS. 10 and 11).

The trench 16 is filled by two different processes to form the isolation structure 1. The low portion of the trench 16 is filled with a thermal oxide layer 23 formed by oxidizing epitaxial silicon, and the dielectric material 24 on the thermal oxide layer 23 is filled by a chemical vapor deposition process or spin-on deposition process. In this instance, the thermal oxide layer 23 is denser than the dielectric material 24, and the layers are separated by an interface 26.

FIGS. 12 to 18 are cross-sectional views showing a method of forming an isolation structure according to one embodiment of the present invention. In this embodiment, as shown in FIG. 12, an upper layer 31 is formed on a substrate 30 (such as a silicon substrate), wherein the upper layer 31 comprises at least one trench 36 which has side surfaces 361 and exposes part of the substrate 30.

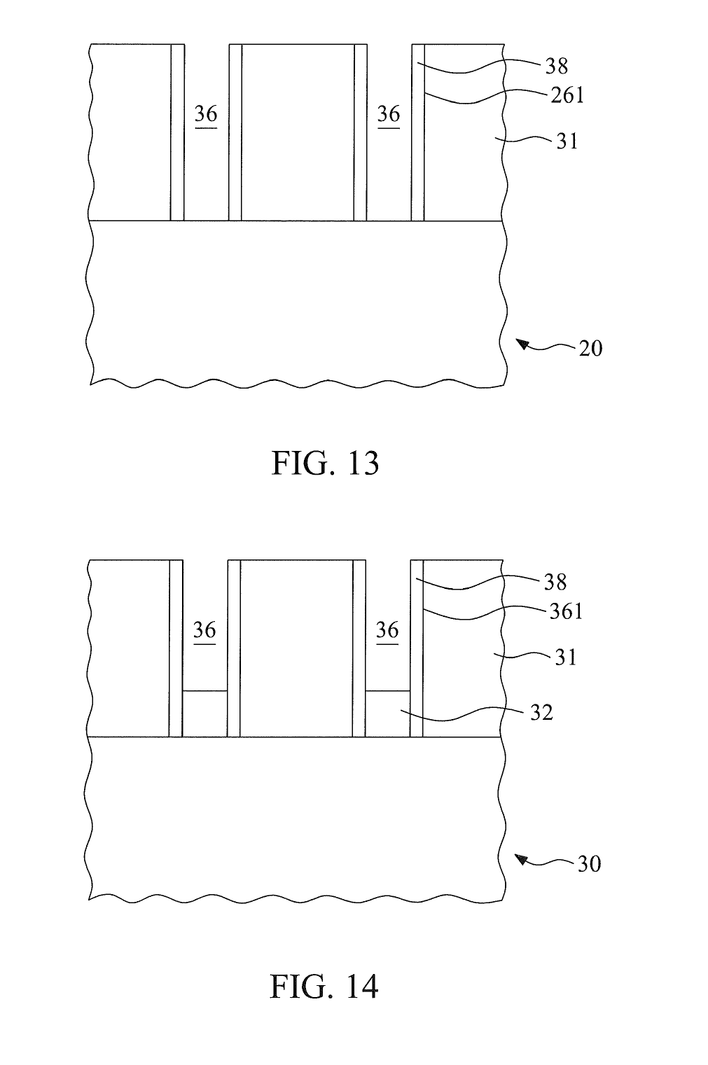

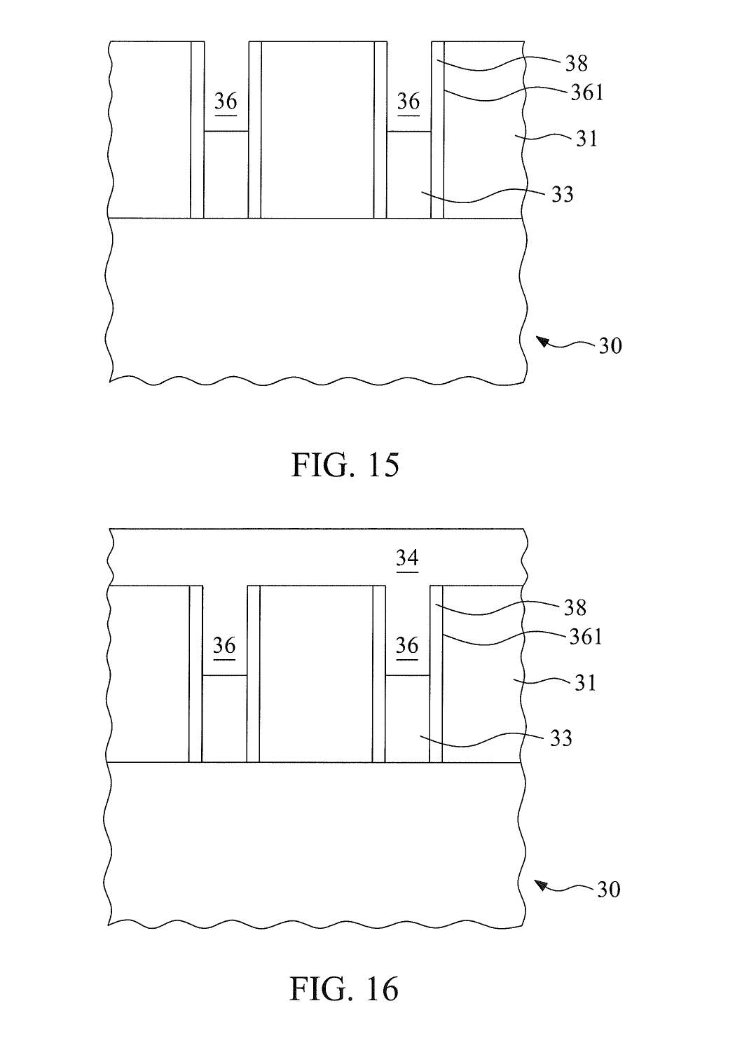

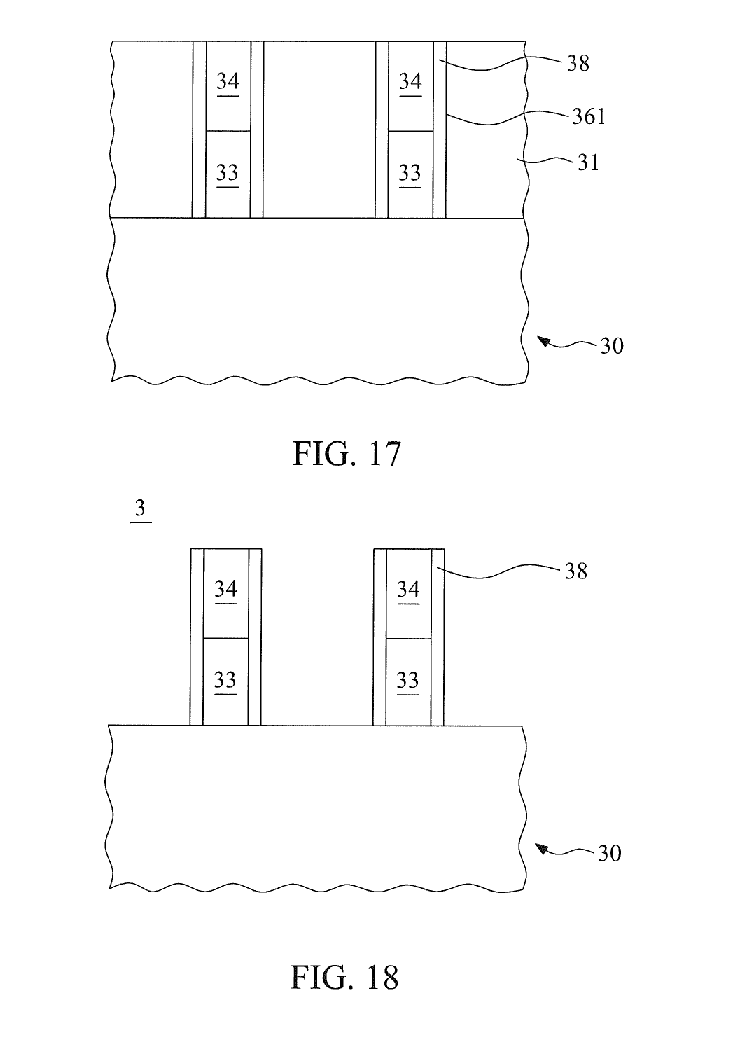

As shown in FIG. 13, an insulating spacer 38 is formed on the side surfaces 361 of the trench 36, and part of the substrate 30 in each trench 36 is exposed. As shown in FIG. 14, an epitaxial silicon layer 32 grows from the substrate 30. As shown in FIG. 15, an epitaxial silicon layer 32 is oxidized to form a thermal oxide layer 33. As shown in FIGS. 15 and 16, a portion of the trench 36 above the thermal oxide layer 33 is filled with a dielectric material 34. It should be noted that undesired dielectric materials 24 may be removed by the chemical-mechanical polishing process or other suitable processes, as shown in FIG. 17.

As shown in FIGS. 17 and 18, the upper layer 31 is removed, so that the insulating spacer 38 is disposed on the side surfaces of the thermal oxide layer 33 and the dielectric material 34. Consequently, an isolation structure 3 formed on the substrate 30 is completed. Conventional processes may then follow to form a semiconductor device such as a memory, microcontroller, analog circuitry, etc.

Materials and forming methods of the epitaxial silicon layer 32, thermal oxide layer 33 and dielectric material 34 can refer to those of the epitaxial silicon layer 22, thermal oxide layer 23 and dielectric material 24 mentioned above, and are not described in detail.

Although the present invention and its objectives have been described in detail, it should be understood that various changes, substitutions and alterations can be made herein without departing from the spirit and scope of the invention as defined by the appended claims. For example, many of the processes discussed above can be implemented using different methodologies, replaced by other processes, or a combination thereof.

Moreover, the scope of the present application is not intended to be limited to the particular embodiments of the process, machine, manufacture, m composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an isolation structure, comprising the steps of:
forming a trench in a substrate, wherein the trench comprises side surfaces and a bottom surface;
forming an insulating spacer on the side surfaces of the trench, the insulating spacer exposing a portion of the substrate;
growing an epitaxial silicon layer above the bottom surface of the trench;
oxidizing the epitaxial silicon layer to form a thermal oxide layer; and
filling a portion of the trench above the thermal oxide layer with a dielectric material.

2. The method of claim 1, wherein the epitaxial silicon layer is located between the insulating spacer.

3. The method of claim 2, wherein the step of oxidizing the epitaxial silicon layer is performed to oxidize at least a portion of the epitaxial silicon layer.

4. The method of claim 2, wherein the step of oxidizing the epitaxial silicon layer is performed to oxidize the epitaxial silicon layer completely.

5. The method of claim 1, wherein the step of oxidizing the epitaxial silicon layer is performed in a steam ambient environment.

6. The method of claim 1, wherein the epitaxial silicon layer is oxidized at a temperature of approximately 800 to 1000 degrees Celsius.

7. The method of claim 1, wherein the portion of the trench above the thermal oxide layer is filled using a spin-on deposition process.

8. The method of claim 1, wherein the portion of the trench above the thermal oxide layer is filled using a chemical vapor deposition process.

9. The method of claim 1, wherein the insulating spacer is formed on the side surfaces of the trench, and the bottom surface of the trench is exposed.

10. The method of claim 1, wherein the insulating spacer is formed on the side surfaces of the trench by atomic layer deposition.

11. The method of claim 1, wherein the insulating spacer is formed on the side surfaces and the bottom surface of the trench, and part of the side surfaces are exposed.

12. The method of claim 1, wherein the insulating spacer is formed on the side surfaces of the trench by chemical vapor deposition.

13. A method of forming an isolation structure, comprising the steps of:
forming an upper layer on a substrate, wherein the upper layer comprises at least one trench having side surfaces and exposing a portion of the substrate;
forming an insulating spacer on the side surfaces of the trench, the insulating spacer exposing a portion of the substrate;
growing an epitaxial silicon layer from the substrate;
oxidizing at least a part of the epitaxial silicon layer to form a thermal oxide layer;
filling a portion of the trench above the thermal oxide layer with a dielectric material; and
removing the upper layer.

14. The method of claim 13, wherein the epitaxial silicon layer is located between the insulating spacer.

15. The method of claim 13, wherein the step of oxidizing the epitaxial silicon layer is performed to oxidize at least a portion of the epitaxial silicon layer.

16. The method of claim 13, wherein the step of oxidizing the epitaxial silicon layer is performed to oxidize the epitaxial silicon layer completely.

17. The method of claim 13, wherein the step of oxidizing the epitaxial silicon layer is performed in a steam ambient environment.

18. The method of claim 13, wherein the epitaxial silicon layer is oxidized at a temperature of approximately 800 to 1000 degrees Celsius.

19. The method of claim 13, wherein the portion of the trench above the thermal oxide layer is filled using a spin-on deposition process.

20. The method of claim 13, wherein the portion of the trench above the thermal oxide layer is filled using a chemical vapor deposition process.
